(19) United States
(12) Patent Application Publication
(10) Pub. No.: US 2020/0321478 A1
(43) Pub. Date: Oct. 8, 2020

(54) TRENCH JUNCTION BARRIER SCHOTTKY DIODE WITH VOLTAGE REDUCING LAYER AND MANUFACTURING METHOD THEREOF

(71) Applicants: NA REN, LOS ANGELES, CA (US); ZHENG ZUO, LOS ANGELES, CA (US); RUIGANG LI, LOS ANGELES, CA (US)

(72) Inventors: NA REN, LOS ANGELES, CA (US); ZHENG ZUO, LOS ANGELES, CA (US); RUIGANG LI, LOS ANGELES, CA (US)

(73) Assignee: AZ Power, Inc, CULVER CITY, CA (US)

(21) Appl. No.: 16/588,196

(22) Filed: Sep. 30, 2019

Related U.S. Application Data
(60) Provisional application No. 62/830,190, filed on Apr. 5, 2019.

(51) Int. Cl. H01L 29/872; H01L 29/16; H01L 29/417; H01L 29/06; H01L 29/08; H01L 29/66; H01L 21/04

(52) U.S. Cl. CPC H01L 29/872; H01L 29/1608; H01L 29/417; H01L 21/0465; H01L 29/08; H01L 29/6606; H01L 29/0603

(57) ABSTRACT

In one aspect, a method for manufacturing a silicon carbide (SiC) multi-Schottky-layer trench junction barrier Schottky diode may include steps of providing a substrate; forming an epitaxial layer on top of the substrate; forming one or more trenches on the epitaxial layer; generating a first implantation region at a bottom portion of each trench; providing an ohmic contact metal on an opposite of the substrate; generating a second implantation region at each corner near a top portion of each trench; and forming a Schottky contact metal to fill in each trench and on top of the epitaxial layer.

### CROSS-REFERENCE TO RELATED APPLICATIONS

This application claims priority under 35 U.S.C. § 119 (e) to U.S. Provisional Patent Application Ser. No. 62/830,190, filed on Apr. 5, 2019, the entire contents of which are hereby incorporated by reference.

### FIELD OF THE INVENTION

The present invention relates to a trench type junction barrier Schottky diode, and more particularly to a trench junction barrier Schottky diode with a voltage reducing layer and the manufacturing method thereof.

### BACKGROUND OF THE INVENTION

Silicon carbide (SiC) diodes have been widely approved for their significant advantages in power applications, especially under high voltage/temperature conditions. In general, SiC Schottky diodes are of interest because of low onset voltage (as compared with that of SiC PN junction diodes) and no reverse recovery. However, reverse leakage current of a pure Schottky diode can be significantly larger under high blocking voltage, caused by image force lowering and tunneling effects at the Schottky interface.

Junction Barrier Schottky (JBS) diode structure was proposed to address this problem, which combines the advantages of Schottky junction and PN junction diodes. In JBS structure, plurality of P regions is disposed between Schottky regions. The depletion layer diffuses from PN junction to exhibit pinch-off below the Schottky contact in reverse blocking mode, which can provide electric field shielding effect. As a result, the electric field strength at the Schottky interface can be reduced and the diode leakage current can be decreased subsequently. The electric field shielding effect can be enhanced by increasing the PN junction depth. However, due to the strong lattice of SiC material, the ion implantation depth is only at most 0.8 μm at an implantation energy as high as 380 keV. Trench structure was introduced to increase the PN junction depth by implanting ions into the bottom and sidewalls of trenches. which is shown in FIG. 3. In this structure, the sidewalls of trenches are designed as P-type region. Since the PN junction has no contribution to the forward conduction due to the wide band-gap of SiC material, the channel resistance between adjacent P-type regions could be high, which is bad for the device forward performance.

To reduce the channel resistance, the PN junction formed by the P-type regions in the sidewalls of the trenches can be replaced with N-type Schottky contact. In other words, P-type regions only exists in the bottom of the trench and trench sidewall is covered with Schottky contact metal to form Schottky junction. For an instance, applying a very low barrier Schottky metal will benefit the forward conduction performance while the reverse leakage current could be significant leaking through high electric field regions, i.e., in the center of the mesa and at the corner of the trench. On the contrary, applying a high barrier Schottky metal can suppress the reverse leakage current, but the forward performance benefit could be limited. To attain a better trade-off between the forward conduction performance and reverse blocking performance, based on the choice of applying a quite high barrier Schottky metal, the present invention introduces a voltage reducing layer in low electric field regions to reduce the forward voltage drop without sacrifice of reverse blocking performance.

### SUMMARY OF THE INVENTION

It is an object of the present invention to provide a trench structure with a voltage reducing layer to enhance both forward conduction performance and reverse blocking performance.

It is another object of the present invention to provide a trench structure with a voltage reducing layer in low electric field regions to reduce the forward voltage drop without sacrifice of reverse blocking performance.

In one aspect, a silicon carbide (SiC) trench junction barrier Schottky diode with a voltage reducing layer may include a substrate, an epitaxial layer, a plurality of trenches, a P-type implantation region, an ohmic contact metal, a N-type implantation region, and a Schottky contact metal.

In one embodiment, the material selected for the ohmic contact metal may include nickel, silver or platinum. The substrate produced from N⁺ type SiC is located on top of ohmic contact metal. In another embodiment, the epitaxial layer produced from N⁻ type SiC is located on top of the substrate, and the epitaxial layer can further be patterned and etched with a first mask layer to form the trenches. In one embodiment, the depth of each trench is about 1 to 50000 angstrom.

The P-type implantation region can be generated at a bottom portion of each trench by ion implantation, and the P-type material may include boron or aluminum, for example. In one embodiment, the thickness of the P-type implantation region is about 1 to 10000 angstrom.

In one embodiment, the N-type implantation region can be formed by ion implantation into the corners of each trench of the epitaxial layer as where the trench sidewall and mesa intersect. In another embodiment, the N-type material can be nitrogen or phosphorus and the impurity concentration is higher than that of epitaxial layer. The depth and width of the N-type implantation region is about 1-20000 angstroms.

The Schottky contact metal is filled into the trenches and formed on the mesas as well. A Schottky junction is then formed between the Schottky contact metal and the epitaxial layer at the trench sidewalls and the mesas.

In another aspect, a method for manufacturing a silicon carbide (SiC) multi-Schottky-layer trench junction barrier Schottky diode may include steps of: providing a substrate, forming an epitaxial layer on top of the substrate, forming one or more trenches on the epitaxial layer, generating an implantation region at a bottom portion of each trench, providing an ohmic contact metal on an opposite of the substrate, depositing a first Schottky contact metal on top of the implantation region in each trench, forming a second Schottky contact metal on the top of the Schottky contact metal with an extension onto each corner of one or more mesas of the epitaxial layer, and forming a third Schottky contact metal on top of the second Schottky contact metal and the mesas not covered by the second Schottky contact metal.

In one embodiment, the step of providing the substrate includes using N⁺ type SiC as a substrate, and the step of forming the epitaxial layer may include forming an epitaxial layer made from N⁻ type SiC on top of the substrate. The step of forming one or more trenches includes the step of patterning, etching and removing a portion of the epitaxial layer with a mask layer to form the trenches. The step of forming the implantation region may include the step of doping P-type impurity with the mask layer into the bottom of the trench openings.

In another aspect, a method for manufacturing a silicon carbide (SiC) multi-Schottky-layer trench junction barrier Schottky diode may include steps of providing a substrate; forming an epitaxial layer on top of the substrate; forming one or more trenches on the epitaxial layer; generating a first implantation region at a bottom portion of each trench; providing an ohmic contact metal on an opposite of the substrate; generating a second implantation region at each corner near a top portion of each trench; and forming a Schottky contact metal to fill in each trench and on top of the epitaxial layer.

In one embodiment, the step of providing the substrate includes using N⁺ type SiC as a substrate, and the step of forming the epitaxial layer may include forming an epitaxial layer made from N⁻ type SiC on top of the substrate. The step of forming one or more trenches includes the step of patterning, etching and removing a portion of the epitaxial layer with a first mask layer to form the trenches. The step of forming the implantation region may include the step of doping P-type impurity with the first mask layer into the bottom of the trench openings.

In another embodiment, the step of providing an ohmic contact metal includes the step of providing an ohmic contact metal underneath the substrate. The step of generating a second implantation region at each top corner of each trench may further include steps of depositing a second mask layer onto a top portion of the epitaxial layer and filling into each trench, patterning the second mask layer, and implanting the N-type impurity into each corner near a top portion of each trench, where the trench sidewall and the mesa intersect. It is noted that the ion implantation is done with a tilted angle to attain design depth and width of the implantation region, and the impurity concentration is higher than that of the epitaxial layer.

It is also noted that the Schottky contact metal to fill in each trench and on top of the epitaxial layer forms a Schottky junction between the Schottky contact metal and the epitaxial layer at the trench sidewall and the mesa.

The present invention is advantageous because instead of PN junction, the trench sidewall of the Schottky diode is designed as Schottky junction to contribute to forward conduction, and the depth of the trench and the P-type region are especially designed to attain a better trade-off between the forward and reverse performance. Moreover, a voltage reducing layer formed by N-type implant is designed in low electric field regions to reduce forward voltage drop. Therefore, the trench structure in the present invention can make a greater use to achieve an improved forward conduction performance without sacrifice of the reverse blocking performance.

### BRIEF DESCRIPTION OF THE DRAWINGS

FIG. 1 is a cross section view of the trench type junction barrier Schottky diode with a voltage reducing layer in the present invention.

FIGS. 2A to 2J are explanatory views for manufacturing processes of the trench type junction barrier Schottky diode a voltage reducing layer in the present invention.

FIG. 3 is a prior art showing a cross sectional structural view of a conventional trench type junction barrier Schottky diode.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

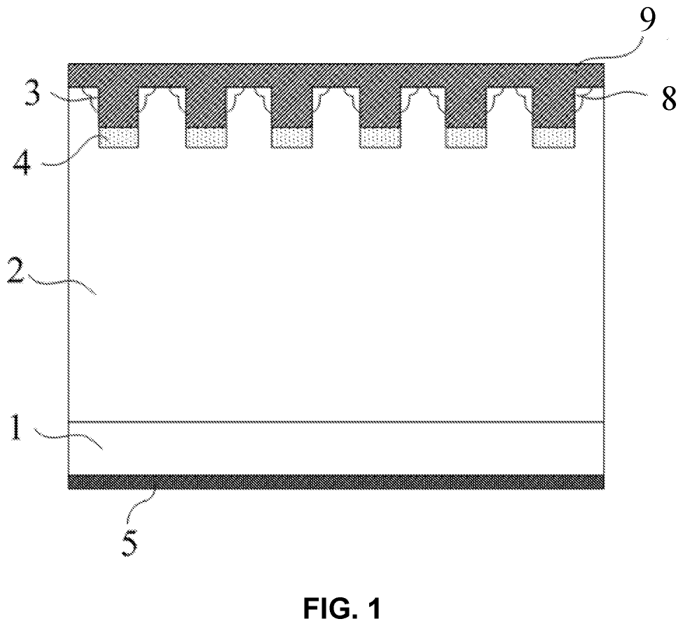

In one aspect, referring to FIG. 1, illustrating a cross sectional view of a silicon carbide (SiC) trench junction barrier Schottky diode with a voltage reducing layer in the present invention, which may include a substrate 1, an epitaxial layer 2, a plurality of trenches 3, a P-type implantation region 4, an ohmic contact metal 5, a N-type implantation region 8, and a Schottky contact metal 9.

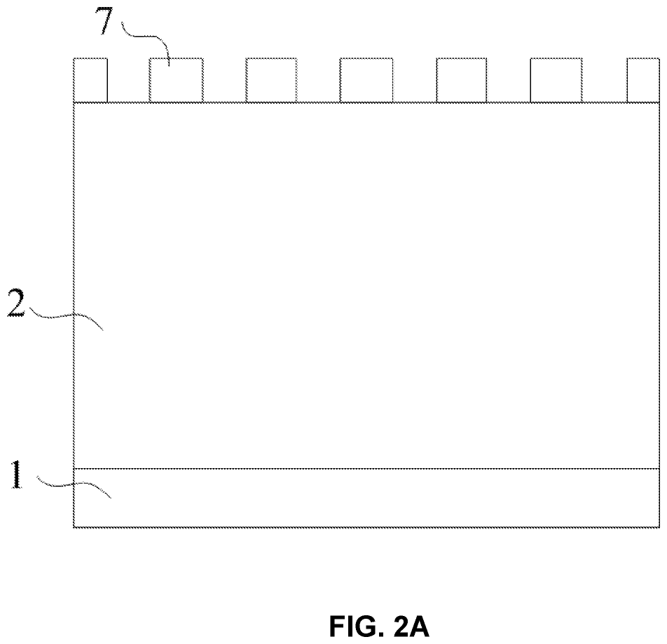

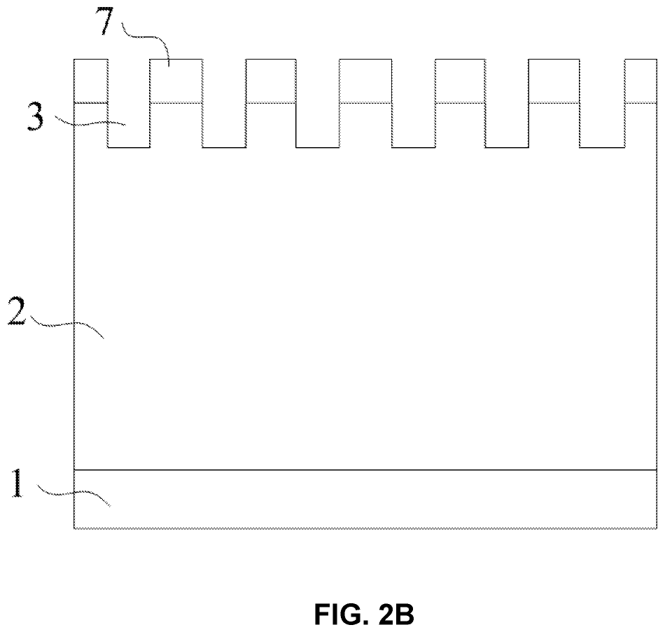

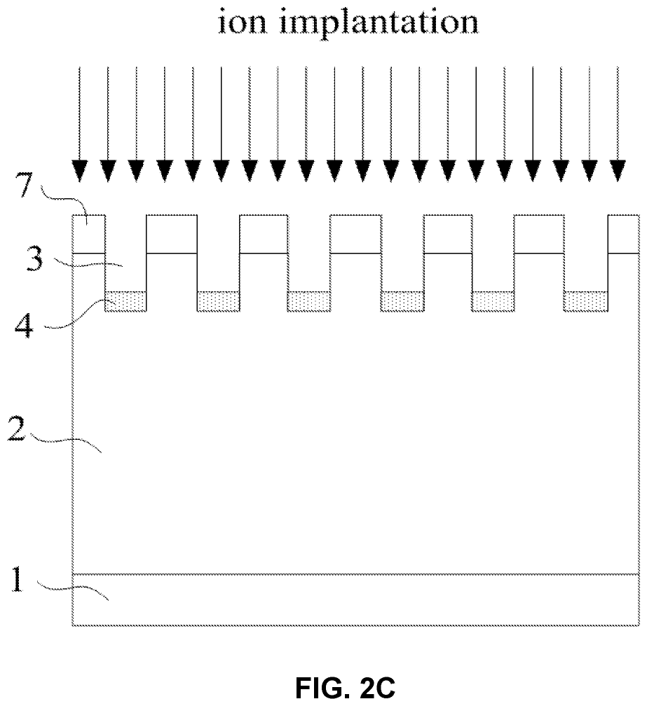

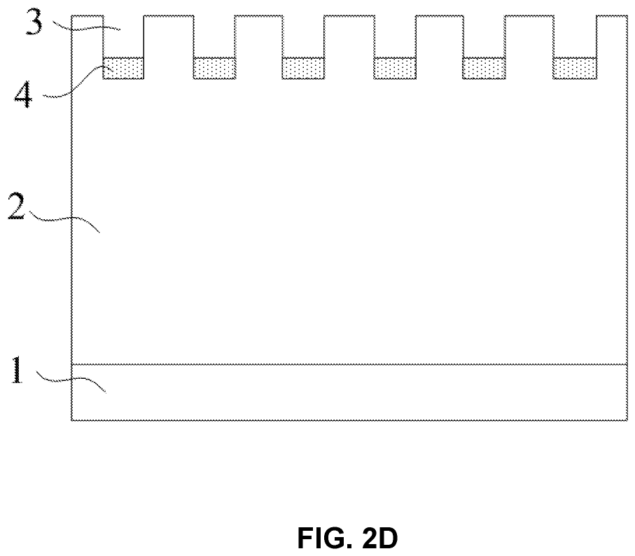

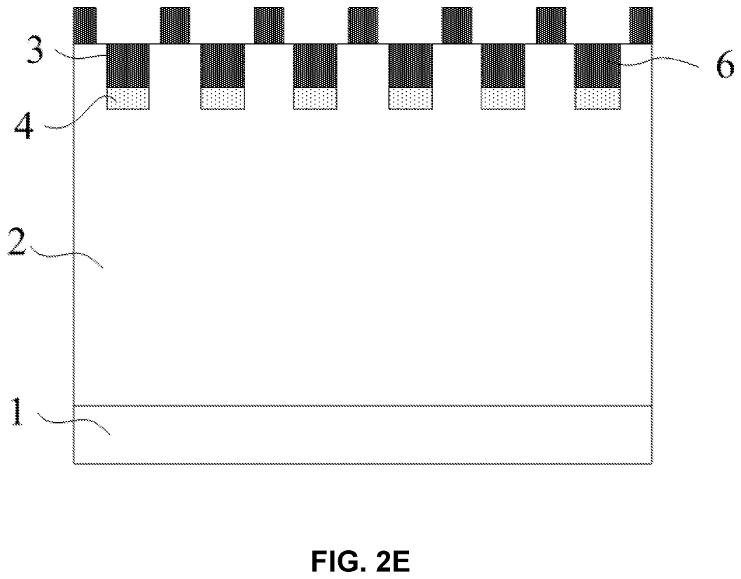

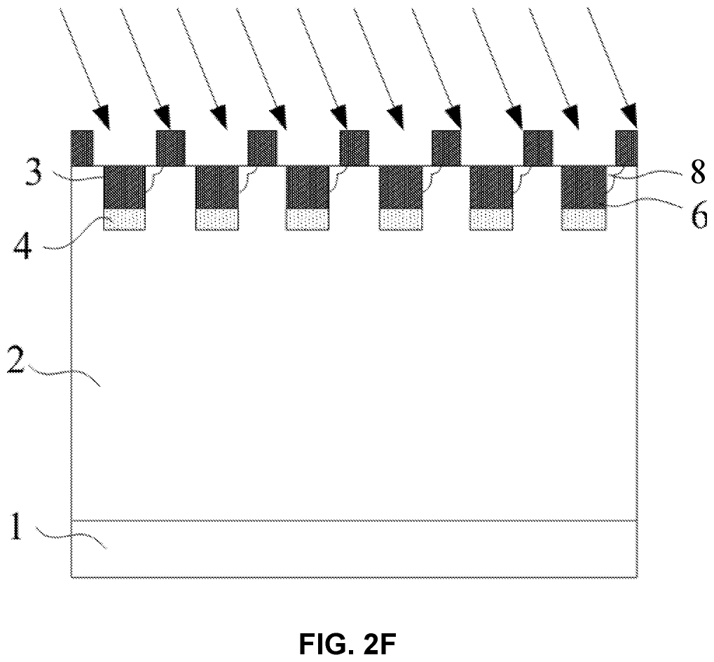

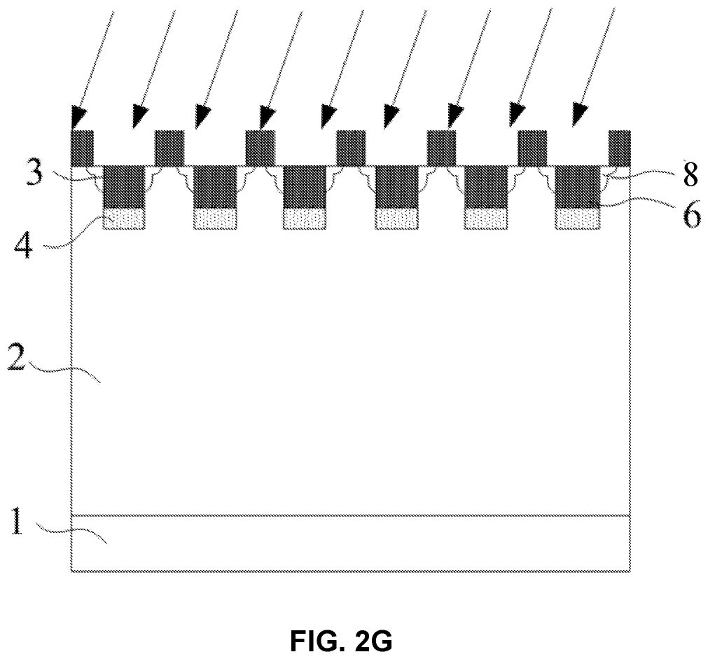

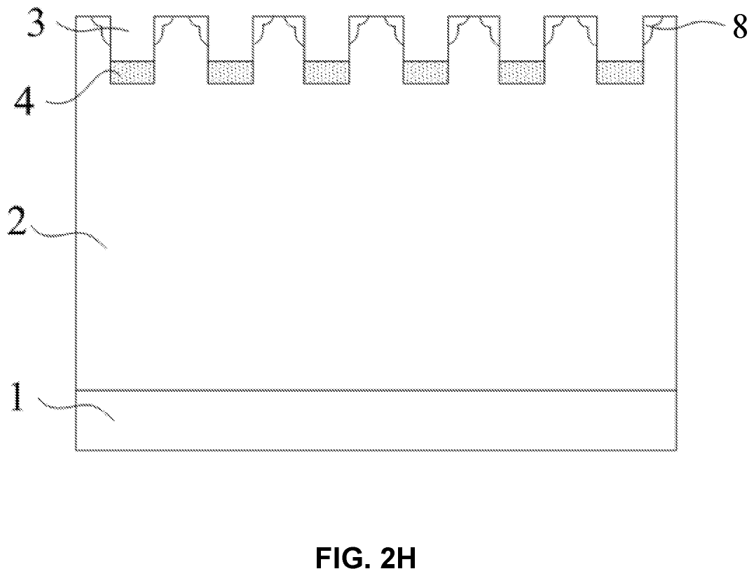

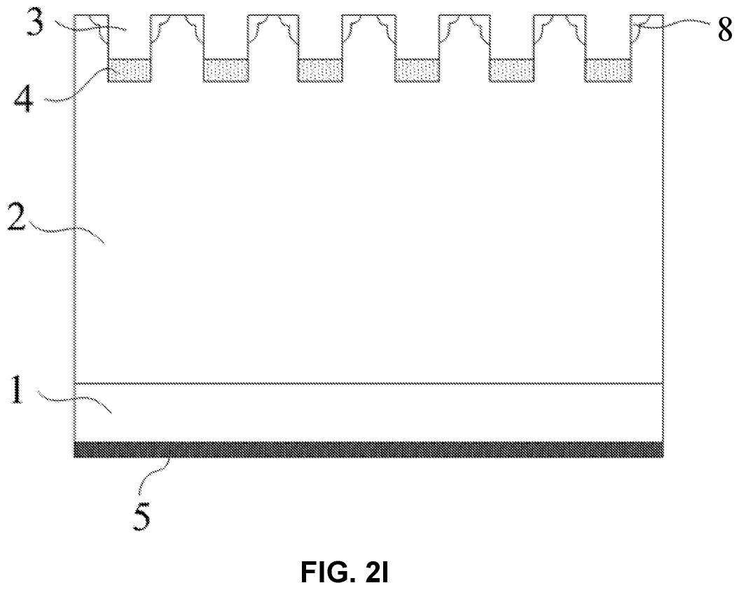

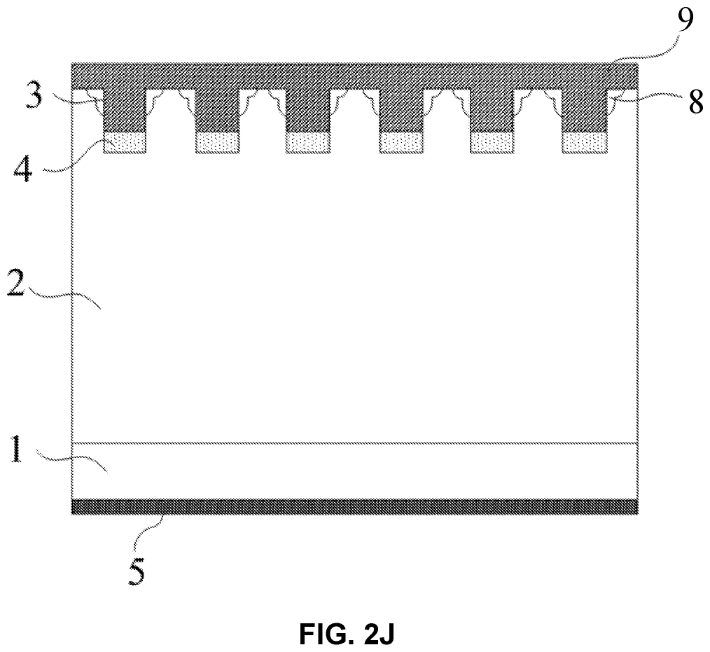

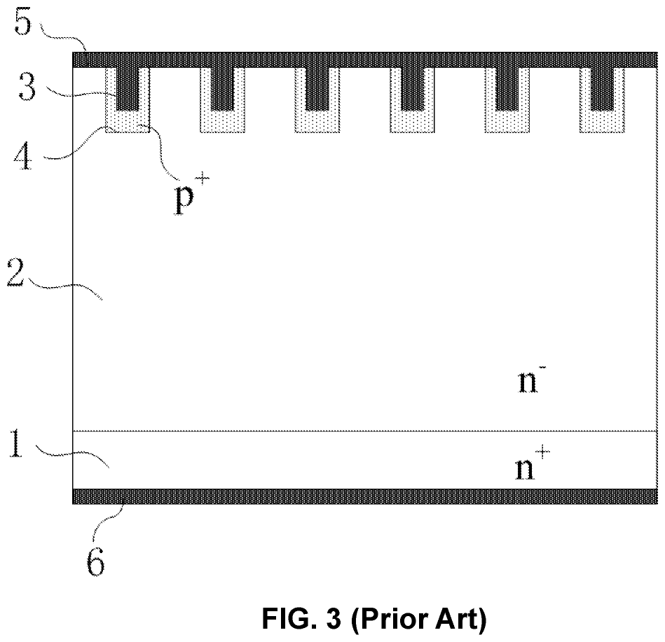

In one embodiment, the material selected for the ohmic contact metal 5 may include nickel, silver or platinum. The substrate 1 produced from N⁺ type SiC is located on top of ohmic contact metal 5. In another embodiment, the epitaxial layer 2 produced from N⁻ type SiC is located on top of the substrate 1, and the epitaxial layer 2 can further be patterned and etched with a first mask layer 7 as shown in FIGS. 2A and 2B to form the trenches 3. In one embodiment, the depth of each trench 3 is about 1 to 50000 angstrom.

The P-type implantation region 4 can be generated at a bottom portion of each trench 3 by ion implantation as shown in FIG. 2C, and the P-type material may include boron or aluminum, for example. In one embodiment, the thickness of the P-type implantation region 4 is about 1 to 10000 angstrom.

In one embodiment, the N-type implantation region 8 can be formed by ion implantation into the corners of each trench 3 of the epitaxial layer 2 as shown in FIGS. 2F and 2G where the trench sidewall and mesa intersect. In another embodiment, the N-type material can be nitrogen or phosphorus and the impurity concentration is higher than that of epitaxial layer. The depth and width of the N-type implantation region 8 is about 1-20000 angstroms.

As shown in FIG. 2J, the Schottky contact metal 9 is filled into the trenches 3 and formed on the mesas as well. A Schottky junction is then formed between the Schottky contact metal 9 and the epitaxial layer 2 at the trench sidewalls and the mesas.

In another aspect, referring to FIG. 2A-2J, a method for manufacturing a silicon carbide (SiC) multi-Schottky-layer trench junction barrier Schottky diode may include steps of: step 301: providing a substrate 1; step 302: forming an epitaxial layer 2 on top of the substrate 1; step 303: forming one or more trenches 3 on the epitaxial layer 2; step 304: generating a first implantation region 4 at a bottom portion of each trench 3; step 305: providing an ohmic contact metal 5 on an opposite of the substrate 1; step 306: generating a second implantation region 8 at each top corner of each trench 3; and step 307: forming a Schottky contact metal 9 to fill in each trench 3 and on top of the epitaxial layer 2.

In one embodiment, the step of providing the substrate 1 includes using N⁺ type SiC as a substrate, and the step of forming the epitaxial layer 2 may include forming an epitaxial layer made from N⁻ type SiC on top of the substrate 1. The step of forming one or more trenches 3 includes the step of patterning, etching and removing a portion of the epitaxial layer with a first mask layer 7 to form the trenches as shown in FIGS. 2A and 2B. In one embodiment, the depth of each trench 3 is about 1 to 50000 angstrom. The step of forming the implantation region 4 may include the step of doping P-type impurity with the first mask layer 7 into the bottom of the trench openings as shown in FIGS. 2C and 2D. In one embodiment, the thickness of the P-type implantation region 4 is about 1 to 10000 angstrom.

In another embodiment, the step of providing an ohmic contact metal 5 includes the step of providing an ohmic contact metal underneath the substrate 1 as shown in FIG. 21. As shown in 2E to 2H, the step of generating a second implantation region 8 at each top corner of each trench 3 may further include steps of depositing a second mask layer 6 onto a top portion of the epitaxial layer 2 and filling into each trench 3, patterning the second mask layer 6, and implanting the N-type impurity into each top corner of each trench 3, where the trench sidewall and the mesa intersect. It is noted that the ion implantation is conducted with a tilted angle to attain design depth and width of the implantation region 8, and the impurity concentration is higher than that of the epitaxial layer 2.

It is also noted that as shown in FIG. 2J, the Schottky contact metal 9 to fill in each trench 3 and on top of the epitaxial layer 2 forms a Schottky junction between the Schottky contact metal 9 and the epitaxial layer 2 at the trench sidewall and the mesa.

The present invention is advantageous because instead of PN junction, the trench sidewall of the Schottky diode is designed as Schottky junction to contribute to forward conduction, and the depth of the trench and the P-type region are especially designed to attain a better trade-off between the forward and reverse performance. Moreover, a voltage reducing layer formed by N-type implant is designed in low electric field regions to reduce forward voltage drop. Therefore, the trench structure in the present invention can make a greater use to achieve an improved forward conduction performance without sacrifice of the reverse blocking performance.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A Schottky diode comprising:
a substrate;
an epitaxial layer deposited on one side of the substrate;
one or more trenches formed on top of the epitaxial layer;
a first implantation region at a bottom portion of each trench;
an ohmic contact metal deposited on the other side of the substrate;
a second implantation region as a voltage reducing layer at each top corner of each trench; and
a Schottky contact metal filling each trench and extending to cover a top surface of the epitaxial layer.

2. The Schottky diode of claim 1, wherein the substrate is made by N⁺ type silicon carbide (SiC), and the epitaxial layer is made by N⁻ type SiC.

3. The Schottky diode of claim 1, wherein a depth of each trench is about 1 to 50000 angstrom.

4. The Schottky diode of claim 1, wherein the first implantation region is doped with P-type impurity.

5. The Schottky diode of claim 1, wherein a thickness of the first implantation region is about 1 to 10000 angstrom.

6. The Schottky diode of claim 1, wherein a Schottky junction is then formed between the Schottky contact metal and the epitaxial layer at trench sidewalls and mesas.

7. The Schottky diode of claim 1, wherein the second implantation region is doped with N-type materials, including nitrogen and phosphorus.

8. A method for manufacturing a Schottky diode comprising steps of:
providing a substrate;
forming an epitaxial layer on top of the substrate;
forming one or more trenches on the epitaxial layer;
generating a first implantation region at a bottom portion of each trench;
providing an ohmic contact metal on an opposite of the substrate;
generating a second implantation region as a voltage reducing layer at each top corner of each trench; and
depositing a Schottky contact metal to fill each trench and extending to cover a top surface of the epitaxial layer.

9. The method for manufacturing a Schottky diode of claim 8, wherein the substrate is made by N⁺ type silicon carbide (SiC), and the epitaxial layer is made by N⁻ type SiC.

10. The method for manufacturing a Schottky diode of claim 8, wherein a depth of each trench is about 1 to 50000 angstrom.

11. The method for manufacturing a Schottky diode of claim 8, wherein a thickness of the P-type implantation region is about 1 to 10000 angstrom.

12. The method for manufacturing a Schottky diode of claim 8, wherein the step of forming one or more trenches includes the step of patterning, etching and removing a portion of the epitaxial layer with a first mask layer to form the trenches.

13. The method for manufacturing a Schottky diode of claim 8, wherein the step of generating a second implantation region at each top corner of each trench further includes steps of depositing a second mask layer onto a top portion of the epitaxial layer and filling into each trench, patterning the second mask layer, and implanting the N-type impurity into each top corner of each trench.

14. The method for manufacturing a Schottky diode of claim 13, wherein the step of implanting the N-type impurity into each top corner of each trench is conducted with a titled angle.

15. The method for manufacturing a Schottky diode of claim 8, wherein a Schottky junction is then formed between the Schottky contact metal and the epitaxial layer at trench sidewalls and mesas.
